(19) United States
(12) Patent Application Publication
(10) Pub. No.: US 2015/0179914 A1
(43) Pub. Date: Jun. 25, 2015

(54) Annealed dielectrics and heat-tolerant conductors for superconducting electronics

(71) Applicant: Intermolecular Inc., San Jose, CA (US)

(72) Inventors: Frank Greer, Pasadena, CA (US); Andy Steinbach, San Jose, CA (US); Wenxian Zhu, E. Palo Alto, CA (US)

(73) Assignee: Intermolecular Inc., San Jose, CA (US)

(21) Appl. No.: 14/138,692

(22) Filed: Dec. 23, 2013

(51) Int. Cl. H01L 39/24; H01L 39/02

(52) U.S. Cl. CPC H01L 39/24; H01L 39/02

(57) ABSTRACT

A interconnect structure for superconducting devices uses a material with a high melting point for the superconductive wiring; examples include refractory metals such as niobium. Because the wiring is tolerant of high temperatures, the interlayer dielectric (e.g., amorphous silicon with or without small amounts of passivants such as hydrogen or fluorine) may be subjected to rapid thermal annealing to reduce defects by driving off excess hydrogen, and optionally partially crystallizing the material.

### BACKGROUND

Related fields include thin-film microwave devices with superconducting components and reduction of defects in dielectrics.

At temperatures <100 mK, amorphous silicon (a-Si) is an insulating dielectric. Its low cost and ease of fabrication make it attractive as an interlayer dielectric (ILD) for superconducting interconnects and components for planar microwave devices, but its loss tangent (˜10⁸) is much larger than that of single-crystal Si (˜10⁷) at microwave frequencies (e.g., 3-300 GHz) and longer infrared frequencies (300-1000 GHz). The loss tangent is believed to be caused by defects occurring during deposition. A lower loss tangent would benefit high-frequency classical devices by reducing signal attenuation, dispersion and jitter. A lower loss tangent would benefit quantum devices, such as rapid single flux quantum (RFSQ) circuits and reciprocal quantum logic (RQL) by increasing coherence times for quantum state signals. Other candidate materials with similar challenges include silicon dioxide (SiO2) and silicon nitride (SiN).

ILD layers are typically 300-1000 nm thick. At this thickness, many surface treatments are ineffective to remove defects from the bulk of the film. This is also an inconvenient thickness to form by the precisely controlled methods of atomic layer deposition (ALD); each ALD cycle creates a monolayer on the order of 0.1 nm thick, therefore a layer hundreds of nm thick would take too long to be cost-effective.

Hydrogenation has been observed to improve a-Si loss tangent in some cases. However, only hydrogen (H) that is strongly bonded to Si helps to reduce loss. H that is trapped in interstices of the a-Si, or that is weakly attracted to dangling bond sites of two neighboring Si atoms, can form a two-level system (TLS) that increases noise and loss. For example, early studies of Josephson-junction-based qubits for quantum computing attributed loss and decoherence primarily to extraneous TLS effects from defects in dielectrics.

TLS effects originate in electrons, atoms, and other material components that may randomly change quantum states in the presence of an oscillating electric or magnetic field such as the microwave-frequency signals transmitted in superconducting microwave devices. One type of TLS in silicon-based interlayer dielectrics is a hydrogen atom, usually from a Si precursor ligand, trapped between two dangling bonds from adjacent Si atoms. Because the Si—H bond is weak, the H easily breaks away from one Si atom and bonds to the other, and can just as easily switch back again.

Therefore, a need exists for methods to reduce the microwave-frequency loss tangent of a-Si films by reducing or eliminating defects, such as dangling bonds, in the bulk of micron-scale films as well as on the surface.

### SUMMARY

The following summary presents some concepts in a simplified form as an introduction to the detailed description that follows. It does not necessarily identify key or critical elements and is not intended to reflect a scope of invention.

In some embodiments of methods for fabricating superconducting interconnects, an ILD layer is formed by chemical vapor deposition (CVD) of a-Si. In some embodiments, the a-Si is hydrogenated. After part or all of the deposition is complete, the a-Si layer may be subjected to rapid thermal annealing (RTA); e.g., heating to about 700-1000 C for 1 second-5 minutes until weakly-bonded H is ejected, the a-Si becomes partially crystallized, or both. Superconducting wiring structures may be formed on, under, or between successive ILD layers by a damascene or dual-damascene process.

The RTA temperature is selected to be less than the melting point of the superconducting wiring material. The superconducting wiring material may be a refractory metal with a high melting point. For example, niobium (Nb) and molybdenum (Mo) are superconducting refractory metals with melting points above 2700 C.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A and 1B conceptually illustrate interconnects and interlayer dielectrics.

FIG. 2 is a flowchart of an example damascene or dual-damascene process for fabricating an interconnect structure.

FIG. 3 is a block diagram of an example of a CVD chamber.

FIGS. 4A and 4B conceptually illustrate the effect of annealing on trapped H in a-Si.

FIG. 5 is a process flowchart for fabricating a superconducting interconnect structure according to some embodiments.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

Unless the text or context clearly dictates otherwise: (1) by default, singular articles “a,” “an,” and “the” (or the absence of an article) may encompass plural variations; for example, “a layer” may mean “one or more layers.” (2) “Or” in a list of multiple items means that any, all, or any combination of less than all the items in the list may be used in the invention. (3) Where a range of values is provided, each intervening value is encompassed within the invention. (4) “About” or “approximately” contemplates up to 10% variation. “Substantially (equal, unchanged, or the like)” contemplates up to 5% variation.

“Substrate,” as used herein, may mean any workpiece on which formation or treatment of material layers is desired. Substrates may include, without limitation, silicon, germanium, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter.

As used herein, a material (e.g. a dielectric material or an electrode material) will be considered to be “amorphous” if it exhibits less than or equal to 20% crystallinity as measured by a technique such as x-ray diffraction (XRD). “Interlayer dielectric,” “intermetallization dielectric,” “bulk insulator,” and “fill dielectric” are used interchangeably herein for an insulating dielectric layer that fills spaces between conducting interconnects (e.g., wiring layers, vias) or between the devices connected by the interconnects. Material properties such as “conductor,” “superconductor,” “semiconductor,” “dielectric,” and “insulator” may vary with temperature for a given material, and shall be used herein to describe the characteristics of the materials at the intended operating temperature of the device in which the materials are used. For example, “forming a superconducting layer” shall mean “forming a layer of a material expected to exhibit superconductivity at the intended operating temperature of the device being fabricated.” “Conformal” shall denote a step coverage of at least 75%.

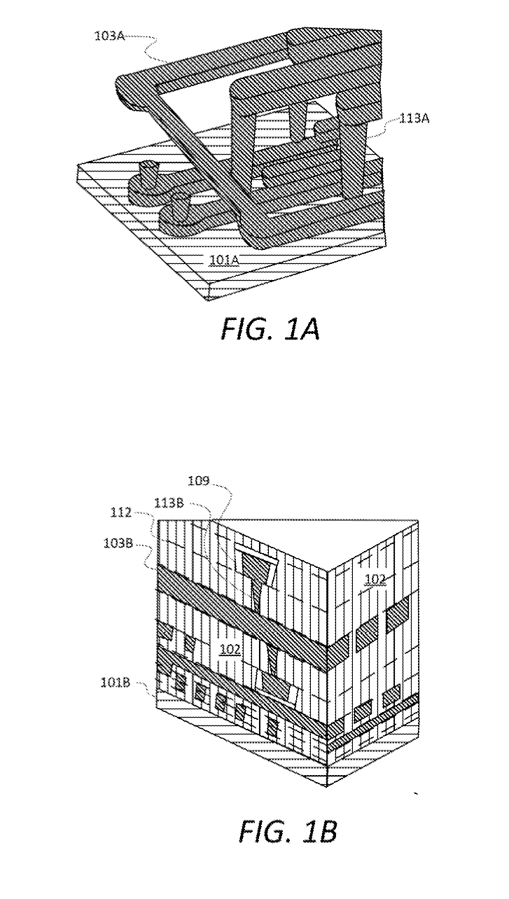

FIGS. 1A and 1B conceptually illustrate interconnects and interlayer dielectrics. T FIG. 1A illustrates multiple layers of interconnects without showing the ILD, to better visualize the three-dimensional network of wirings 103a and vias 113A built up on substrate 101A. Substrate 101A may have other layers and structures below those shown. Typically, each wiring 103A begins as a blanket conductive layer formed on an ILD layer. The blanket layer is etched to form the separate conductive paths, and the resulting wiring is buried in another ILD layer. Vias 113A may be constructed similarly to wirings 103A, or alternatively they may be constructed by patterning the ILD; forming openings through the ILD and filling the openings with conductive material. Longer vias that penetrate more than one layer may be constructed as multiple segments, with the length of each segment being the thickness of one layer. Some formations may involve chemical-mechanical polishing (CMP) of either an ILD layer or a conductive layer to expose parts of buried structures. The conductive elements (wirings and vias) may be any suitable superconducting material with a melting point above about 1000 C, such as refractory metals, their alloys, and their nitrides.

FIG. 1B is a schematic cutaway view of several interconnect and device layers. Here, the ILD 102 is shown between the structures; heavy dotted lines 112 delineate the separately formed layers. The illustrated structures include some wirings 103B and vias 113B, and also some components 109 (e.g., transistors, capacitors, switches, resistors, resonators; in a superconducting device, the components may include Josephson junctions).

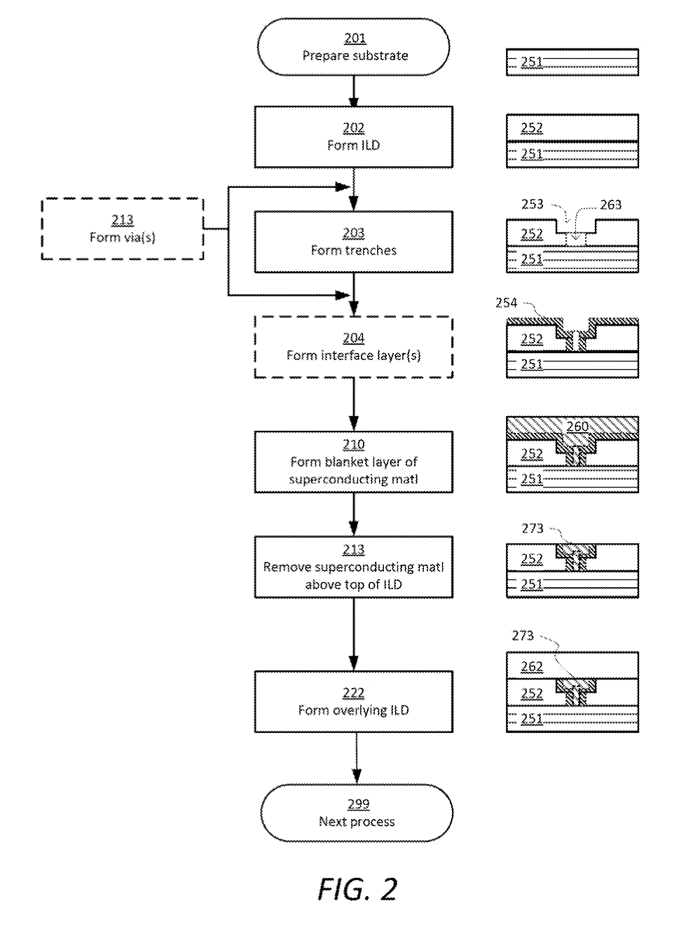

FIG. 2 is a flowchart of an example damascene or dual-damascene process for fabricating an interconnect structure. The step 201 of preparing a substrate may or may not include providing an underlying wiring and/or or via layer (e.g., a superconducting wiring or via layer) exposed on the surface of substrate 251, depending on the structure of the interconnect and the stage of the fabrication. In step 202, a blanket ILD layer 252 is formed over substrate 251. For example, the ILD layer may be an amorphous silicon layer deposited by CVD and annealed. The ILD layer may be 300-1000 nm thick, e.g., 350-450 nm thick.

In step 203, the ILD is patterned to create physical spaces for the conductive (e.g., superconducting) pathways. Trenches 253 are formed in ILD layer 252. Optionally, vias 263 may be formed in ILD layer 253 either before or after trenches 253. Trenches 253 may only extend through part of the ILD, while vias 263 may extend all the way through the ILD to a contact or connection structure in an underlying layer. In some single-damascene processes, vias 263 may be formed in ILD layer 252 without trenches 253. Trenches 253 and/or vias 263 may be formed by dry etching, wet etching, or any other suitable method known in the art. In step 204, trenches 253 and/or vias 263 may optionally be lined with one or more conformal interface layers 254 (e.g., barrier layers, seed layers, and the like). In step 210, a blanket layer of superconducting material is formed to fill trenches 253 and/or vias 263.

In step 213, part of superconducting layer 260 (and in some embodiments part of interface layer(s) 254) is removed (e.g., by CMP or another known suitable planarization method) to expose the top of ILD 252, leaving interconnect structure 273 embedded in ILD 252. In step 222, another ILD 262 is formed over ILD 252 and interconnect structure 273 to complete the insulation of interconnect structure 273.

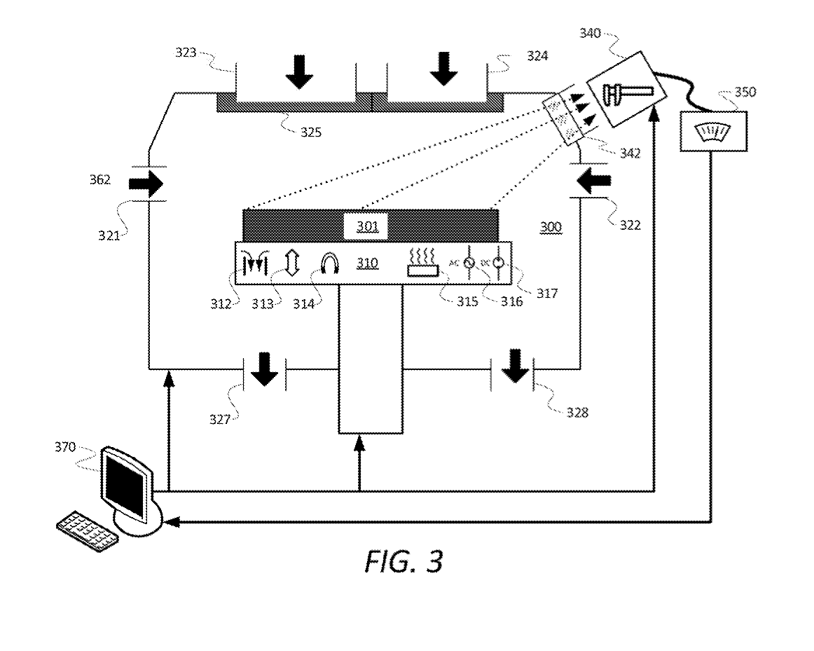

FIG. 3 is a block diagram of an example of a CVD chamber. Inside CVD chamber 300, substrate 301 is held by a substrate holder 310. Substrate holder 310 may be configured with vacuum 312 (for example, a vacuum chuck to grip the substrate); motion 313 in any direction, which may include tilt and rotation; a magnetic field source 314; heater or temperature control 315; or sources of AC 316 or DC 317 bias voltage. Chamber 300 also has gas inlets 321, 322, 323, 324 for CVD precursors, buffer gases, and purge gases. Exhausts 327, 328 may be coupled to vacuum pumps to remove gases from chamber 300. Some of the inlets may feed through one or more diffusers or “showerheads” 325. Measurement system 340 may monitor substrate 301 through measurement ports 342. The measurements from measurement system 340 may be collected by a monitoring system 350.

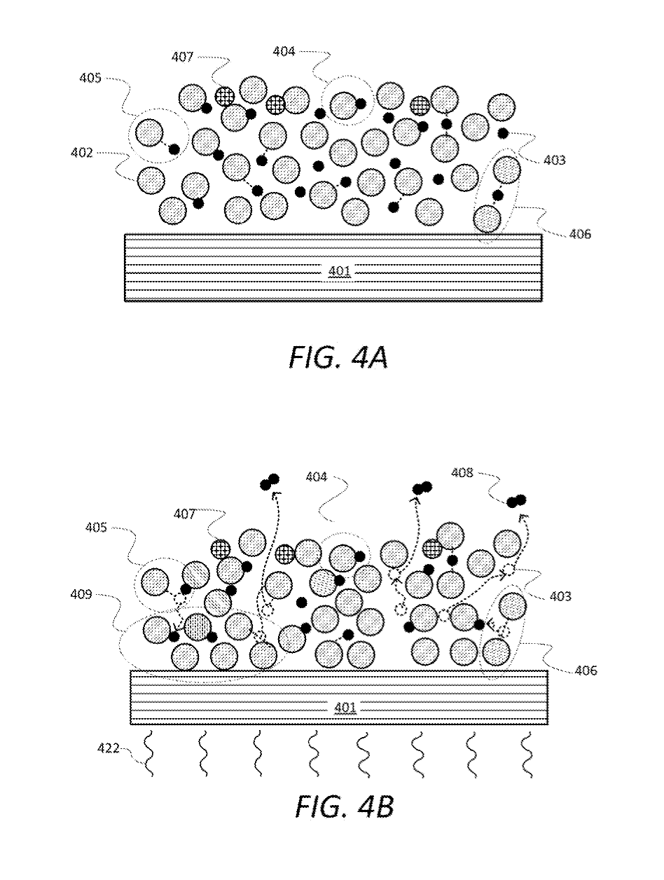

FIGS. 4A and 4B conceptually illustrate the effect of annealing on trapped H in a-Si. FIG. 4A conceptually illustrates a layer of hydrogenated a-Si with defects. This illustration is not intended to represent the hydrogenation level, defect density, or exact structure of any particular form of a-Si, but merely to introduce the graphic symbols for the various elements and bonds. The layer may be hydrogenated by using an H-containing Si CVD precursor such as silane, disilane or trisilane, or by depositing the Si in an H-containing ambient, or both. On substrate 401, which may have underlying layers and structures, the Si atoms 402 and H atoms 403 are randomly arranged in the amorphous layer. A strongly bonded Si—H pair 404 is represented by tangential contact of the Si and H. A weakly bonded Si—H pair 405 is represented by a dotted-line connection. In some cases, an H atom is weakly bonded to two neighboring Si atoms with a shared weak bond 406. Optionally, another element 407 may be present (e.g., from a fluorine (F) surface passivation treatment).

In FIG. 4B, the substrate is heated in a rapid thermal anneal (RTA) process. The anneal temperature may be between about 700 and 1000 C, e.g., 950 C, the anneal duration may be about 1 second to 5 minutes, and the chamber pressure may be less than or equal to 1 atmosphere. Heat 422 mobilizes H atoms that are not strongly bonded, such as interstitials 403 and those in shared bonds 406 and other weak bonds 405. Some may encounter a strong-bonding site 404 and others may combine into H₂ 408 and outgas. In some embodiments, the heat may begin to crystallize the a-Si, forming localized regions of relatively ordered lattice structure 409. In some embodiments, high-temperature rapid annealing may crystallize the a-Si more than lower-temperature prolonged annealing.

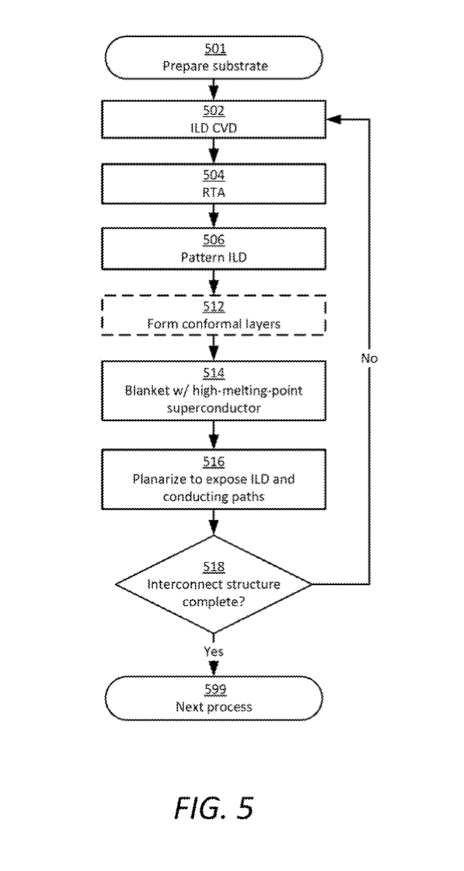

FIG. 5 is a process flowchart for fabricating a superconducting interconnect structure according to some embodiments. Step 501, preparing the substrate, may include a pre-clean (by a wet or dry process) or the patterning or other partial removal of an underlying layer. Step 502, forming the ILD by CVD, may include deposition of a-Si from a Si precursor such as silane, disilane, or trisilane. The deposition temperature may be 500-650 C (e.g., 525-575 C or 550 C). Optionally, if more hydrogen content is desired, hydrogen gas or a different H-containing gas may be added to the ambient during the Si deposition.

Step 504, rapid thermal annealing, may include heating the substrate to 700-1000 C (e.g., 950 C) for 1-60 sec (e.g., 30 sec) at a chamber pressure up to 1 atmosphere. The RTA temperature is preferably well below the melting point of the high-melting-point superconductor being used for the conductive paths. In some embodiments, the heating may expel weakly bonded hydrogen from the ILD by mobilizing it to form H₂ and diffuse through the layer to exit at the surface. Other passivants that are heavier or more tightly bonded, such as fluorine, may remain in place during the annealing. In some embodiments, the heating may partially crystallize the a-Si. In step 506, patterning the ILD, trenches and/or vias are formed in the locations of the intended superconducting paths.

Optional step 512, forming conformal layers such as liners, barriers, and seed layers, may be done after ILD patterning 506. Conformal layer formation 512 may include CVD, atomic layer deposition (ALD), epitaxy, or plating. The choice is partially dependent on the depth and aspect ratio of the trenches and/or vias to be lined. Materials used in the conformal layers preferably have melting points greater than the RTA temperature; for example, they may be refractory metals, or alloys or nitrides of refractory metals.

In step 514, forming a blanket layer of a high-melting-point superconductor, the superconductor may be deposited by CVD or physical vapor deposition (PVD; e.g., sputtering, evaporation) or any other suitable method for filling the trenches and/or vias. In step 516, the blanket layer of superconducting material is planarized to expose the ILD and the superconductor-filled trenches and/or vias (conductive paths). If more interconnect layers are needed, another ILD may be formed over the exposed ILD and conductive paths as step 502 of an additional process cycle. If the interconnect structure is complete at step 518, next process 599 may commence.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A method, comprising:
forming a first superconducting interconnect structure on a substrate;
forming a first amorphous silicon layer over the first superconducting interconnect structure; and
heating the substrate to a temperature between 700 C and 1000 C for a time between 1 second and 5 minutes.

2. The method of claim 1, wherein the melting point of an interconnect material in the first superconducting interconnect structure is greater than about 2700 C.

3. The method of claim 1, wherein the first superconducting interconnect structure comprises a refractory metal, a refractory metal alloy, or a refractive metal nitride.

4. The method of claim 3, wherein the refractory metal comprises niobium or molybdenum.

5. The method of claim 1, wherein a hydrogen content of the first amorphous silicon layer silicon layer is less after the heating than before the heating.

6. The method of claim 1, wherein a crystallinity of the first amorphous silicon layer is greater after the heating than before the heating.

7. The method of claim 1, wherein a thickness of the first amorphous silicon layer is between about 300 nm and 1000 nm.

8. The method of claim 1, wherein a thickness of the first amorphous silicon layer is between about 350 nm and 450 nm.

9. The method of claim 1, wherein the forming of the first amorphous silicon layer comprises chemical vapor deposition.

10. The method of claim 9, wherein a substrate temperature during the chemical vapor deposition is between about 500 C and 650 C.

11. The method of claim 9, wherein a substrate temperature during the chemical vapor deposition is between about 525 C and 575 C.

12. The method of claim 1, wherein the temperature during the heating is about 950 C.

13. The method of claim 1, wherein the heating continues for about 30 seconds.

14. The method of claim 1, wherein a concentration of fluorine in the first amorphous silicon layer is substantially unchanged after the heating.

15. The method of claim 1, further comprising forming a second superconducting interconnect structure over the first amorphous silicon layer.

16. The method of claim 15, wherein the forming of the second superconducting interconnect structure comprises a damascene process.

17. The method of claim 15, wherein the forming of the second superconducting interconnect structure comprises a dual-damascene process.

18. The method of claim 15, wherein the second superconducting interconnect structure comprises a conductive path formed in a trench in the first amorphous silicon layer.

19. The method of claim 15, wherein the second superconducting interconnect structure comprises a conductive path formed in a via in the first amorphous silicon layer.

20. The method of claim 15, further comprising:
forming a second amorphous silicon layer over the second superconducting interconnect structure; and
heating the substrate to a temperature between 700 C and 1000 C for a time between 1 second and 5 minutes.
